(19) United States
(12) Patent Application Publication
(10) Pub. No.: US 2026/0076016 A1
(43) Pub. Date: Mar. 12, 2026

(54) LIGHT EMITTING DEVICE

(71) Applicant: SEOUL SEMICONDUCTOR CO., LTD., Ansan-si (KR)

(72) Inventor: Ji Ho KIM, Ansan-si (KR)

(21) Appl. No.: 19/319,673

(22) Filed: Sep. 4, 2025

Related U.S. Application Data
(60) Provisional application No. 63/693,105, filed on Sep. 10, 2024.

(51) Int. Cl. H10H 29/85; H01L 25/075

(52) U.S. Cl. CPC H10H 29/8585; H10H 29/8581; H10H 29/8582; H10W 90/00

(57) ABSTRACT

Provided is a light emitting device including: a plurality of light emitters including semiconductor layers; and a heat conductor unit that provides a light emitter arrangement region in which the plurality of light emitters are arranged, in which the heat conductor unit includes a heat-dissipation heat conductor for dissipating heat generated from the plurality of light emitters, and an area of the heat-dissipation heat conductor, in a plan view, is larger than an area of the light emitter arrangement region.

### CROSS REFERENCE TO RELATED APPLICATION

This application claims priority from and the benefit of United States Provisional Patent Application No. 63/693,105, filed on Sep. 10, 2024, which is hereby incorporated by reference for all purposes as if fully set forth herein.

### BACKGROUND

### Field

Embodiments of the invention relate generally to a light emitting device.

### Discussion of the Background

A light emitting device emits light and is used in various fields such as display devices, automotive lamps, and general lighting. In general, automotive light emitting devices are installed at the front end of a vehicle to project light forward, helping the driver secure visibility. Such a light emitting device may include a plurality of light emitters that emit light to form a low beam pattern and a high beam pattern according to the driver's operation. The light emitting device may generate heat when emitting light.

Recently, due to the need for increasing performance and dependability, there is a greater need for light-emitting devices with improved thermal dissipation characteristics.

The above information disclosed in this Background section is only for understanding of the background of the inventive concepts, and, therefore, it may contain information that does not constitute prior art.

### SUMMARY

Embodiments of the disclosure may provide a light emitting device that efficiently dissipates heat, thereby increasing heat dissipation efficiency and improving reliability.

The embodiments of the disclosure may provide a light emitting device with a stable structure that resists damage such as cracks even under heat generation or thermal stress.

The embodiments of the disclosure may provide a light emitting device with high luminance by improving light extraction efficiency.

Additional features of the inventive concepts will be set forth in the description which follows, and in part will be apparent from the description, or may be learned by practice of the inventive concepts.

In an aspect, a light emitting device according to an embodiment includes: a plurality of light emitters configured to emit light; and a heat conductor unit configured to provide a light emitter arrangement region in which the plurality of light emitters are arranged, in which the heat conductor unit includes a heat-dissipation heat conductor configured to dissipate heat generated from the plurality of light emitters, and an area of the heat-dissipation heat conductor, in a plan view, is larger than an area of the light emitter arrangement region.

The heat conductor unit may include an upper heat conductor electrically connected to the plurality of light emitters; and a support substrate including the heat-dissipation heat conductor and configured to support the upper conductor.

The light emitting device in which the light emitter arrangement region may overlap the heat-dissipation heat conductor in the plan view.

The area of the heat-dissipation heat conductor, in the plan view, may be in the range of about 30% to about 80% of an area of the heat conductor unit. At least one corner of the heat-dissipation heat conductor may have a rounded shape, the heat conductor unit may include an insulator, and the heat-dissipation heat conductor may be arranged such that its peripheral surface is surrounded by the insulator.

The heat-dissipation heat conductor may be formed to have a first length in a horizontal direction, a second length in a thickness direction, and a third length perpendicular to the first length and the second length, and a ratio of the first length to the second length is different from a ratio of the third length to the second length.

The heat conductor unit may include a first insulator disposed between the heat-dissipation heat conductor and the plurality of light emitters so that the heat-dissipation heat conductor and the plurality of light emitters are insulated from each other, and a thickness of the first insulator is lower than a thickness of the heat-dissipation heat conductor.

The heat conductor unit may further include a second insulator disposed below the first insulator to cover at least one of top and bottom surfaces of the heat-dissipation heat conductor, and a thickness of the second insulator may be greater than the thickness of the first insulator.

The light emitting device may further include a support heat conductor configured to support the second insulator to dissipate heat generated from the plurality of light emitters together with the heat-dissipation heat conductor.

The second insulator may include carbon fiber.

In an aspect, the light emitting device may further includes a plurality of controllers configured to control the plurality of light emitters, in which the upper heat conductor includes a plurality of upper heat conductors, and the plurality of upper heat conductors extend from the plurality of controllers toward the light emitter arrangement region so that the plurality of controllers are electrically connected to the plurality of light emitters.

An edge of the heat-dissipation heat conductor may be arranged to intersect an imaginary line connecting one of the plurality of controllers and the light emitter positioned closest to the one controller among the plurality of light emitters in the plan view.

The upper heat conductor my include a plurality of upper heat conductors, and the heat conductor unit may further provide: a first arrangement region, located near the light emitter arrangement region, in which some of the plurality of upper heat conductors are arranged; and a second arrangement region, located farther away from the light emitter arrangement region than the first arrangement region, in which others of the plurality of upper heat conductors are arranged.

A density of some of the plurality of upper heat conductors arranged in the first arrangement region may be greater than a density of others of the plurality of upper heat conductors arranged in the second arrangement region.

The plurality of light emitters may include: a first light emitter; and a second light emitter that is spaced apart from the first light emitter and is not electrically connected to the first light emitter. Each of the first light emitter and the second light emitter may include: a second-first heat conductor electrically connected to the heat-conductor unit; a second-second heat conductor electrically connected to the heat-conductor unit and spaced apart from the second-first heat conductor; and a light emitting unit electrically connected to the second-first heat conductor and the second-second heat conductor to generate light.

One of the plurality of upper heat conductors may be positioned between the second-first heat conductor of the first light emitter and the second-second heat conductor of the second light emitter.

A separation distance between the second-first heat conductor of the first light emitter and the second-second heat conductor of the second light emitter may be greater than a separation distance between the second-first heat conductor and the second-second heat conductor of the first light emitter.

In the plan view, at least some of the plurality of upper heat conductors may be bent in a direction different from their extending directions.

In an aspect, a light emitting device according to another embodiment includes: a plurality of light emitters configured to emit light; and a heat conductor unit configured to provide a light emitter arrangement region in which the plurality of light emitters are arranged, in which the heat conductor unit includes a heat-dissipation heat conductor configured to dissipate heat generated from the plurality of light emitters, and an area of the heat-dissipation heat conductor, when viewed in a first direction, is larger than an area of the light emitter arrangement region.

A light emitting device according to still another embodiment includes: a plurality of light emitters configured to emit light; and a heat conductor unit configured to provide a light emitter arrangement region in which the plurality of light emitters are arranged, in which the heat conductor unit includes a heat-dissipation heat conductor configured to dissipate heat generated from the plurality of light emitters, and an area of the heat-dissipation heat conductor, in a plan view, is larger than an area of the light emitter arrangement region.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the inventive concepts and are incorporated in and constitute a part of this specification, illustrate embodiments, and together with the description serve to explain the inventive concepts.

FIG. 1 is a schematic plan view showing a light emitting device according to an embodiment of the present disclosure.

FIG. 2 is a schematic diagram showing a first example in which a heat-dissipation heat conductor of the light emitting device according an embodiment of the present disclosure is supported on a second insulator.

FIG. 3 is a schematic diagram showing a second example in which the heat-dissipation heat conductor of the light emitting device according an embodiment of the present disclosure is supported on the second insulator.

FIG. 4 is a schematic diagram showing a third example in which the heat-dissipation heat conductor of the light emitting device according an embodiment of the present disclosure is supported on the second insulator.

FIG. 5 is a schematic diagram showing a light emitting device according to another embodiment of the present disclosure.

FIG. 6 is a schematic diagram showing a light emitting device according to still another embodiment of the present disclosure.

FIG. 7 is a schematic diagram showing a light emitting device according to still another embodiment of the present disclosure.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, the specific configuration of a light emitting device 1 according to an embodiment of the present disclosure will be described with reference to the drawings.

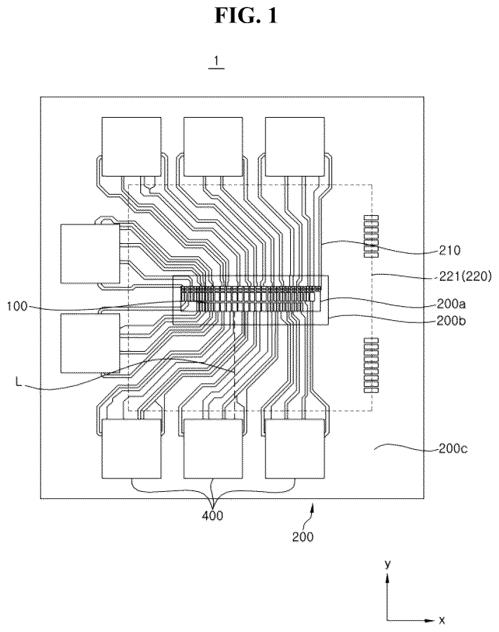

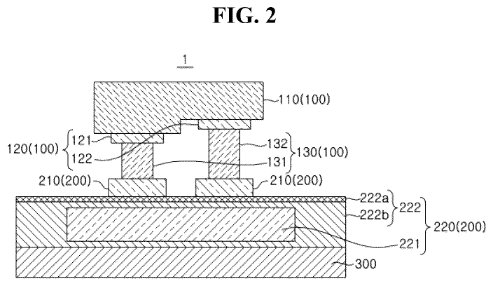

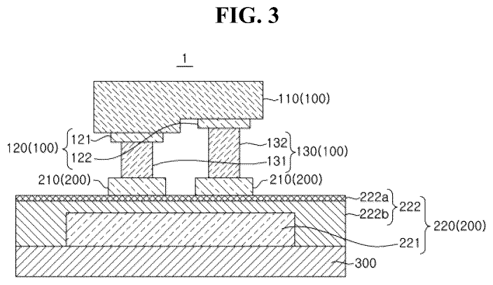

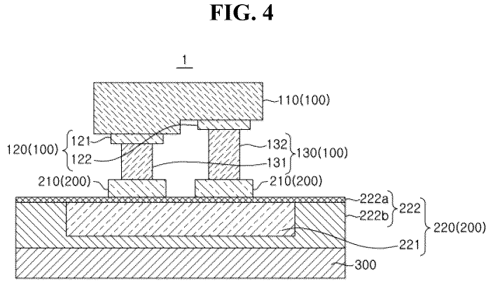

FIG. 1 is a schematic plan view showing a light emitting device according to an embodiment of the present disclosure. FIG. 2 is a schematic diagram showing a first example in which a heat-dissipation heat conductor of the light emitting device according an embodiment of the present disclosure is supported on a second insulator. FIG. 3 is a schematic diagram showing a second example in which the heat-dissipation heat conductor of the light emitting device according an embodiment of the present disclosure is supported on the second insulator. FIG. 4 is a schematic diagram showing a third example in which the heat-dissipation heat conductor of the light emitting device according an embodiment of the present disclosure is supported on the second insulator. Referring to FIGS. 1, 2, 3, and 4, the light emitting device 1 according an embodiment of the present disclosure may emit light by receiving power from an external source. The light emitting device 1 may be applied to a vehicle headlamp, but the present disclosure is not limited thereto. For example, the light emitting device 1 may be disposed at the front of a vehicle and emit light toward a lens to form at least one of a high beam pattern and a low beam pattern. The light emitting device 1 may include a light emitter 100, a heat conductor unit 200, a support heat conductor 300, and a controller 400.

The light emitter 100 may be provided as a plurality of light emitter that emit light. The plurality of light emitters 100 may emit light to form at least one of a high beam pattern and a low beam pattern. For example, some of the plurality of light emitters 100 may emit light to form the high beam pattern, and others of the plurality of light emitters 100 may emit light to form the low beam pattern. The size of some of the plurality of light emitters 100 may be formed to be larger than the size of others of the plurality of light emitters 100.

The plurality of light emitters 100 may be arranged in a light emitter arrangement region 200a of the heat conductor unit 200, which will be described later. For example, the plurality of light emitters 100 may be arranged in the light emitter arrangement region 200a and spaced apart from each other in a horizontal direction (or first direction, x direction) in the light emitter arrangement region 200a. In addition, the plurality of light emitters 100 may also be arranged in a vertical direction (or second direction, y direction), which is perpendicular to the first direction and the height direction, in the light emitter arrangement region 200a.

The length of the plurality of light emitters 100 arranged in the first direction (or x direction) may be formed to be greater than the length of the plurality of light emitters 100 arranged in the second direction (or y direction). The plurality of light emitters 100 arranged in the first direction (or x direction) and the plurality of light emitters 100 arranged in the second direction (or y direction) may have different areas in one region. Among the plurality of light emitters 100, the light emitters 100 arranged in the second direction (or y direction) may have an area that is about three times or more that of the light emitters 100 arranged in the first direction (or x direction). A greater current can be applied to the light emitter 100 with a larger area to maintain a constant current density in the light emitter 100. For example, the light emitters 100 arranged in the second direction (or y direction) may be applied with three times or more current than the light emitters 100 arranged in the first direction (or x direction). When a larger amount of current is applied, more heat is generated, and for efficient heat dissipation, the area of a first heat conductor 120, which will be described later, of the light emitters 100 arranged in the second direction (or y direction) may be larger than the area of the first heat conductor 120 of the light emitters 100 arranged in the first direction (or x direction), and may be larger by about three times or more. More efficiently, the area of the first heat conductor 120 of the light emitters 100 arranged in the second direction (or y direction) may be about four times or more compared to the area of the first heat conductor 120 of the light emitters 100 arranged in the first direction (or x direction).

In addition, the plurality of light emitters 100 may be arranged in rows and columns. When the first direction (or x direction) corresponds to the rows and the second direction (or y direction) corresponds to the columns, the plurality of light emitters 100 arranged in the first row may have a narrower area than the plurality of light emitters 100 arranged in the second row or the third row that is spaced apart (spaced downward in FIG. 1) from the first row.

For example, the sum of the areas of the plurality of light emitters 100 arranged in each row may be different for each row. For example, the sum of the areas of the plurality of light emitters 100 in the first row and the second row may be smaller than the sum of the areas of the plurality of light emitters 100 in the third row or the fourth row. The sum of the areas of the plurality of light emitters 100 arranged in the first row or the second row may be about 12 mm². The sum of the areas of the plurality of light emitters 100 in the third row may have an area of about 30 mm² or more, which is at least about 2.5 times greater than the sum of the areas of the plurality of light emitters 100 in the first or second row. Further, the area of the plurality of light emitters 100 in the fourth row may have an area of about out e² or more, which is less than the area of those in the third row and more than twice the area of those in the first or second. This enables design of the light irradiation area by region.

Furthermore, the number of light emitters 100 arranged in each column may vary. For example, two light emitters 100 may be arranged in the first column, three light emitters 100 may be arranged in the second column, three light emitters 100 may be arranged in the third column, and four light emitters 100 may be arranged in the fourth column. This allows for a reduction in the design complexity of the projection light. For example, when the light emitting device 1 is used in a headlamp, the plurality of light emitters 100 arranged in the first row having a smaller area may correspond to the low beam region, and the plurality of light emitters 100 arranged in the second row or the third row having a larger area may emit light corresponding to the high beam pattern region. For example, the beam angle of the plurality of light emitters 100 arranged in the first row may be wider than the beam angle of the plurality of light emitters 100 arranged in the third row or the fourth row. In addition, the irradiation distance of the plurality of light emitters 100 arranged in the first row may be shorter than the irradiation distance of the plurality of light emitters 100 arranged in the second row or the fourth row.

Further, the plurality of light emitters 100 may have first heat conductors 120 of different sizes. When the area of the light emitter 100 is large, the first heat conductor 120 may also be formed to have a large area. For example, the area of the first heat conductor 120 of the light emitter 100 arranged in the third row or fourth row may be formed larger than the area of the first heat conductor 120 of the light emitter 100 arranged in the first row or second row. For example, the area of the first heat conductor 120 in the third or fourth row may be 3 to about 5 times larger than that in the first or second row. The area of the first heat conductor 120 may increase proportionally to the size of the light emitter 100. Since the area of the first heat conductor 120 may proportionally increase with the size of the light emitter 100, the structural stability of the light emitting device 1 can be improved.

Each of the plurality of light emitters 100 may include a light emitting unit 110, a first heat conductor 120, and a second heat conductor 130.

The light emitting unit 110 may generate light. The overall thickness of the light emitting unit 110 may be in the range of about 1 μm to about 10 μm in a thickness direction. The light emitting unit 110 may include one or more of aluminum gallium arsenide (AlGaAs), gallium arsenide phosphide (GaAsP), aluminum gallium indium phosphide (AlGaInP), gallium phosphide (GaP), indium gallium nitride (InGaN), aluminum gallium phosphide (AlGaP), and zinc selenide (ZnSe). The light emitting unit 110 may include a first conductive semiconductor layer, a second conductive semiconductor layer, and an active layer.

The first conductive semiconductor layer may be electrically connected to a 1-1 (first-first) heat conductor 121, which will be described later. The first conductive semiconductor layer may include n-type impurities (e.g., Si, Ge, Sn), in which case the first conductive semiconductor layer may be an n-type semiconductor layer. However, this is merely an example, and the first conductive semiconductor layer may also include p-type impurities.

The active layer may be laminated on the first conductive semiconductor layer. For example, the active layer may be positioned between the first conductive semiconductor layer and the second conductive semiconductor layer.

The second conductive semiconductor layer may be laminated on the active layer and electrically connected to the 1-2 (first-second) heat conductor 122. The second conductive semiconductor layer may include p-type impurities (e.g., Mg, Sr, Ba). For example, the second conductive semiconductor layer may be a p-type semiconductor layer. However, it is merely an example, and the second conductive semiconductor layer may also include n-type impurities.

The first heat conductor 120 may be electrically connected to the light emitting unit 110. For example, the first heat conductor 120 may be electrically connected to the first conductive semiconductor layer and the second conductive semiconductor layer. For example, the first heat conductor 120 may be a chip pad. In addition, the first heat conductor 120 may include the 1-1 (first-first) heat conductor 121 and the 1-2 (first-second) heat conductor 122.

The 1-1 (first-first) heat conductor 121 may be disposed in a region of the first conductive semiconductor layer and may be electrically connected to the first conductive semiconductor layer.

The 1-2 (first-second) heat conductor 122 may be disposed in a region of the second conductive semiconductor layer and may be electrically connected to the second conductive semiconductor layer.

The areas of the 1-1 (first-first) heat conductor 121 and the 1-2 (first-second) heat conductor 122 may be different from each other. The area of the 1-2 (first-second) heat conductor 122, which generates more heat, may be formed larger than that of the 1-1 (first-first) heat conductor 121 to efficiently dissipate heat. However, the present disclosure is not limited to the above, and the areas of the 1-1 (first-first) heat conductor 121 and the 1-2 (first-second) heat conductor 122 may be formed to be the same. When the areas of the 1-1 (first-first) heat conductor 121 and the 1-2 (first-second) heat conductor 122 are the same, the light emitter 100 may be placed on the heat conductor unit 200 without tilting left and right, so that the light emitting device 1 can be designed to have a stable structure.

The second heat conductor 130 may be disposed in a region of the heat conductor unit 200 to be positioned between the first heat conductor 120 and the heat conductor unit 200. For example, the second heat conductor 130 may be electrically connected to an upper heat conductor 210, which will be described later. For example, the second heat conductor 130 may be an electrode pad. The second heat conductor 130 may include a 2-1 (second-first) heat conductor 131 and a 2-2 (second-second) heat conductor 132.

The 2-1 (second-first) heat conductor 131 may be disposed in a region of the heat conductor unit 200 to be positioned between the 1-1 (first-first) heat conductor 121 and the heat conductor unit 200. The 2-1 (second-first) heat conductor 131 may be electrically connected to the 1-1 (first-first) heat conductor 121 and the heat conductor unit 200. In addition, the 2-1 (second-first) heat conductor 131 may be electrically connected to the first conductive semiconductor layer of the light emitting unit 110. For example, the 2-1 (second-first) heat conductor 131 may be electrically connected to the semiconductor layer containing n-type impurities.

The 2-2 (second-second) heat conductor 132 may be disposed in a region of the heat conductor unit 200 to be positioned between the 1-2 (first-second) heat conductor 122 and the heat conductor unit 200. The 2-2 (second-second) heat conductor 132 may be electrically connected to the light emitting unit 110 and the heat conductor unit 200. In addition, the 2-2 (second-second) heat conductor 132 may be arranged to be spaced apart from the 2-1 (second-first) heat conductor 131. The 2-2 (second-second) heat conductor 132 may be electrically connected to the second conductive semiconductor layer. For example, the 2-2 (second-second) heat conductor 132 may be connected to the semiconductor layer containing p-type impurities.

The 2-2 (second-second) heat conductor 132 and the 2-1 (second-first) heat conductor 131 may be spaced apart from each other. An air layer in which heat becomes highly concentrated may be formed between the 2-2 (second-second) heat conductor 132 and the 2-1 (second-first) heat conductor 131. To address the heat accumulation caused by the formation of the air layer, an insulation material may be filled between the 2-2 (second-second) heat conductor 132 and the 2-1 (second-first) heat conductor 131. For example, the space between the 2-2 (second-second) heat conductor 132 and the 2-1 (second-first) heat conductor 131 may be filled with an underfill material of epoxy or silicone or a material such as pure silicone rubber (PSR), for reducing heat accumulation while maintaining electrical separation between the two conductors.

In a plan view, the sum of the areas of the 2-1 (second-first) heat conductor 131 and the 2-2 (second-second) heat conductor 132 may be formed to occupy in the range of about 40% to about 90% of the area of the light emitting unit 110, which ensures that a sufficient area is secured for effective heat dissipation.

The heat conductor unit 200 may support a plurality of light emitters 100. For example, the heat conductor unit 200 may be a printed circuit board (PCB) including a circuit section or a lead frame substrate. In addition, the heat conductor unit 200 may include one or more of Cu, Zn, Au, Ni, Al, Mg, Cd, Be, W, Mo, Si, Ag, and Fe, or an alloy composed of some of these materials. However, it is merely an example, and a second insulator 222b of the heat conductor unit 200, which will be described later, may include one or more of insulation materials such as FR1, CEM-1, FR4, and fluororesin. For example, FR1 may be a material in which copper foil and laminated paper are laminated, and CEM-1 may be a material in which copper foil, glass fiber fabric, laminated paper, and glass fiber fabric are sequentially laminated. In addition, FR-4 may be a material in which copper foil and glass fiber material or glass fiber fabric are laminated. Moreover, the heat conductor unit 200 may include ceramics such as alumina (Al₂O₃), aluminum nitride (AlN), and ZTA (Zirconia Toughened Alumina). In addition, the heat conductor unit 200 may include a light emitter arrangement region 200a, a first arrangement region 200b, and a second arrangement region 200c.

The light emitter arrangement region 200a may be a region where the plurality of light emitters 100 are arranged. The length of the light emitter arrangement region 200a in the first direction may be defined, in the plan view, as the distance from the left edge of the light emitter 100 positioned closest to the left side (one side) of the heat conductor unit 200 to the right edge of the light emitter 100 positioned closest to the right side (the other side opposite to the one side) of the heat conductor unit 200, among the plurality of light emitters 100. The length of the light emitter arrangement region 200a in the second direction may be defined, in the plan view, as the length from the upper edge of the light emitter 100 positioned closest to the upper side of the heat conductor unit 200 to the lower edge of the light emitter 100 positioned closest to the lower side of the heat conductor unit 200, among the plurality of light emitters 100. The length of the light emitter arrangement region 200a in the first direction may be greater than the length of the light emitter arrangement region 200a in the second direction. For example, the edge of the light emitter arrangement region 200a may be formed in a rectangular shape by extending along the edges of at least some of the plurality of light emitters 100, but the present disclosure is not limited thereto.

The first arrangement region 200b may be a region where some of a plurality of upper heat conductors 210 are arranged. In addition, some of the upper heat conductors 210 may be arranged in the first arrangement region 200b, and others of the upper heat conductors 210 may be arranged in the second arrangement region 200c. The first arrangement region 200b may be located near the light emitter arrangement region 200a. For example, the first arrangement region 200b may surround the light emitter arrangement region 200a in the plan view. For example, one side of each upper heat conductor 210 to be electrically connected to the light emitter 100 may be arranged in the first arrangement region 200b. The density of some of the plurality of upper heat conductors 210 arranged in the first arrangement region 200b may be greater than that of others of the plurality of upper heat conductors 210 arranged in the second arrangement region 200c. The density of the plurality of upper heat conductors 210 may increase toward the light emitter arrangement region 200a, which facilitates heat dissipation generated in the light emitter arrangement region 200a where a large amount of heat is generated, thereby lowering the thermal resistance and improving the reliability of the light emitters 100. The area of the first arrangement region 200b may be the same as the area of a heat-dissipation heat conductor 221, which will be described later.

The second arrangement region 200c may be a region where others of the plurality of upper heat conductors 210 are arranged, which will be described later. The second arrangement region 200c may be located farther away from the light emitter arrangement region 200a than the first arrangement region 200b. The second arrangement region 200c may be a region from the edge of the first arrangement region 200b to the edge of the heat-conductor unit 200 in the heat-conductor unit 200. For example, the first arrangement region 200b may be arranged between the second arrangement region 200c and the light emitter arrangement region 200a. The density of others of the plurality of upper heat conductors 210 arranged in the second arrangement region 200c may be smaller than the density of some of the plurality of upper heat conductors 210 arranged in the first arrangement region 200b, and the production cost may be lowered by reducing the density of the upper heat conductors 210 in the region farther away from the light emitters 100 where heat is generated.

In addition, the heat conductor unit 200 may include an upper heat conductor 210 and a support substrate 220.

The upper heat conductor 210 may be supported (or disposed) on the support substrate 220 and electrically connected to the plurality of light emitters 100 and the controller 400. For example, the upper heat conductor 210 may be a circuit section, wiring, or wiring pattern of the heat conductor unit 200.

The upper heat conductor 210 may extend from a plurality of controllers 400 toward the light emitter arrangement region 200a to electrically connect the plurality of light emitters 100 and the plurality of controllers 400. One side region of the upper heat conductor 210 may be electrically connected to the plurality of light emitters 100. In addition, one side region of the upper heat conductor 210 may be located in the first arrangement region 200b or the light emitter arrangement region 200a. The upper heat conductor 210 may have a shape that extends from the light emitter arrangement region 200a, which is adjacent to the light emitter 100, toward the second arrangement region 200c. Through this structure, the heat generated by the light emitter 100 can diffuse from the light emitter arrangement region 200a to the first arrangement region 200b, thereby lowering the temperature of the light emitter arrangement region 200a. The other side region, opposite to one side region, of the upper heat conductor 210 may be connected to any one of the plurality of controllers 400. The other side region of the upper heat conductor 210 may be located in the second arrangement region 200c, allowing heat to be transferred to a wider area. As a result, the temperature of the light emitter 100 may be lowered, and its reliability can be improved. The thickness of the upper heat conductor 210 may be formed smaller than the height of the light emitter 100, which lowers the production cost. In addition, the area of the upper heat conductor 210 may be formed larger than that of the light emitter 100, which allows heat to diffuse over a wider surface area. As a result, the temperature of the light emitter 100 may be lowered, and reliability may be improved.

Further, the density of some of the plurality of upper heat conductors 210 arranged in the first arrangement region 200b in the first direction (or x direction) may be greater than the density of others of the plurality of upper heat conductors 210 arranged in the second arrangement region 200c in the first direction (or x direction). For example, the spacing between the plurality of upper heat conductors 210 in the first arrangement region 200b may be smaller than the spacing between the plurality of upper heat conductors 210 in the second arrangement region 200c. For example, a gap between two upper heat conductors 210 placed in the second arrangement region 200c may be in the range of about 2 to about 4 times wider than a gap between two upper heat conductors 210 placed in the first arrangement region 200b. Since these plurality of upper heat conductors 210 may perform a heat dissipation function, increasing the density of the plurality of upper heat conductors 210 near the plurality of light emitters 100 may enhance the heat dissipation performance.

In addition, at least some of the plurality of upper heat conductors 210 may be bent in a direction different from the direction in which they extend to be connected to the plurality of controllers 400 and the plurality of light emitters 100, in the plan view. At least some of the plurality of upper heat conductors 210 may be bent multiple times as they extend. The bent regions can increase the area of the upper heat conductors 210, which facilitates heat dissipation and improves heat dissipation performance. However, it is only an example, and the shape of each of the plurality of upper heat conductors 210 is not limited thereto.

Meanwhile, the plurality of light emitters 100 may be grouped into a plurality of groups while being electrically connected to the plurality of upper heat conductors 210. For example, some of the plurality of light emitters 100 may be grouped into a first group while being electrically connected to some of the plurality of upper heat conductors 210, and others of the plurality of light emitters 100 may be grouped into a second group while being electrically connected to others of the plurality of upper heat conductors 210. The light emitters 100 included in the first group and the light emitters 100 included in the second group may not be electrically connected to each other. The light emitters 100 included in the first group and the light emitters 100 included in the second group may operate independently. The light emitters 100 included in the first group and the light emitters 100 included in the second group may emit light for forming the same beam pattern, or light for forming different beam patterns. For example, the light emitters 100 included in the first group may implement a low beam, and the light emitters 100 included in the second group may implement a high beam.

The support substrate 220 may be disposed on a surface of the upper heat conductor 210. In addition, the support substrate 220 may be disposed on a surface of the support heat conductor 300. For example, the support substrate 220 may be disposed between the upper heat conductor 210 and the support heat conductor 300. The height of the support substrate 220 may be greater than the height of the upper heat conductor 210. Heat may be dissipated to the outside through the support substrate 220. The support substrate 220 may include a heat-dissipation heat conductor 221 and an insulating layer 222.

The heat-dissipation heat conductor 221 may transfer heat generated from the plurality of light emitters 100 to other regions. For example, the heat-dissipation heat conductor 221 may be a heat sink. The heat-dissipation heat conductor 221 may be made of a metal material including a heat-dissipating material with electrical conductivity. In particular, the heat-dissipation heat conductor 221 may be made of one or more of Cu, Zn, Au, Ni, Al, Mg, Cd, Be, W, Mo, Si, Ag, and Fe, or an alloy composed of some of these. However, the present disclosure is not limited thereto, and the heat-dissipation heat conductor 221 may include a heat-dissipating material with insulating properties, such as alumina (Al₂O₃), aluminum nitride (AlN), boron nitride (BN), diamond, and beryllium oxide (BeO).

The heat-dissipation heat conductor 221 may be arranged such that its peripheral surface is surrounded by the insulator 222. As a result, electrical stability can be improved. The area of the heat-dissipation heat conductor 221 may be larger than the area of the light emitter arrangement region 200a. For example, in the plan view, the area of the heat-dissipation heat conductor 221 may be larger than the area of the light emitter arrangement region 200a. Accordingly, heat generated by the light emitter 100 may be efficiently discharged to the outside through the heat-dissipation heat conductor 221. Further, when viewed in the first direction (or x direction), the area of the heat-dissipation heat conductor 221 may be larger than the area of the light emitter arrangement region 200a. For example, the area of one side surface of the heat-dissipation heat conductor 221 may be larger than the area of the light emitter arrangement region 200a. The cross-sectional area of a side surface of the heat-dissipation heat conductor 221 may be at least about 1.2 times larger than the cross-sectional area of the light emitter arrangement region 200a. In addition, when viewed in the second direction (or y direction), the area of the heat-dissipation heat conductor 221 may be larger than the area of the light emitter arrangement region 200a. For example, the cross-sectional area of the other side surface, perpendicular to the side surface, of the heat-dissipation heat conductor 221 may be larger than the cross-sectional area of the light emitter arrangement region 200a. The area of the other side surface, perpendicular to the side surface, of the heat-dissipation heat conductor 221 may be at least about 1.4 times larger than the area of the light emitter arrangement region 200a. Additionally, in the plan view, an area of the heat-dissipation heat conductor 221 may be larger than an area of the light emitter arrangement region 200a. In the plan view, the area of the heat-dissipation heat conductor 221 may be at least about five times larger than the area of the light emitter arrangement region 200a. When the area of the heat-dissipation heat conductor 221 is larger than the area of the light emitter arrangement region 200a, the area available to absorb heat in the heat conductor unit 200 may increase, which lowers the thermal resistance of the light emitting device 1 and improves its reliability.

The heat-dissipation heat conductor 221 may have a first length in the first direction, a second length in a height direction (or thickness direction), and a third length in the second direction. The ratio of the first length and the second length of the heat-dissipation heat conductor 221 may be different from the ratio of the third length and the second length. The height of the heat-dissipation heat conductor 221 may be greater than the height of the light emitter 100 and the height of the upper heat conductor 210. The height of the heat-dissipation heat conductor 221 may be about 1.2 times or more the height of the light emitter 100 and the height of the upper heat conductor 210. By forming the heat-dissipation heat conductor 221 with a greater height, its capacity to absorb and store heat increases, which lowers the thermal resistance of the light emitting device 1 and improves its reliability.

In the plan view, the edge of the heat-dissipation heat conductor 221 may be located between the edge of the light emitter arrangement region 200a and the edge of the heat conductor unit 200. For example, the minimum area of the heat-dissipation heat conductor 221, in the plan view, may be equal to the area of the light emitter arrangement region 200a. For example, the minimum area of the heat-dissipation heat conductor 221 may be formed in a rectangular shape. As a result, heat from the light emitter arrangement region 200a can be released to the outside through the heat-dissipation heat conductor 221, thereby improving reliability. Further, when the area of the heat-dissipation heat conductor 221, in the plan view, is the maximum area, the edge of the heat-dissipation heat conductor 221 may be located near the edge of the heat conductor unit 200. As a result, electrical stability can be improved. The area of the heat-dissipation heat conductor 221, in the plan view, may be formed to be about 30% or more and about 80% or less of the area of the heat conductor unit 200. This enables improvement in thermal conductivity while reducing process costs. Furthermore, the area of the heat-dissipation heat conductor 221 may be the same as the area of the first arrangement region 200b. In addition, in the plan view, the edge of the heat-dissipation heat conductor 221 may intersect a virtual line L connecting one of the plurality of controllers 400 and the light emitter 100 positioned closest to the one controller 400 among the plurality of light emitters 100.

The heat-dissipation heat conductor 221 may overlap at least some of the plurality of light emitters 100 in the plan view. For example, the heat-dissipation heat conductor 221 may overlap the light emitter arrangement region 200a. The heat-dissipation heat conductor 221 may be arranged such that its peripheral surface is surrounded by the insulator 222. The heat-dissipation heat conductor 221 may be arranged to overlap an imaginary horizontal plane passing through the center of a second insulator 222b, which will be described later. In addition, at least one corner of the heat-dissipation heat conductor 221 may have a rounded shape. This can improve corner stress concentration, thereby enhancing structural stability.

The insulator 222 may be disposed on a region of the heat-dissipation heat conductor 221. The insulator 222 may surround the peripheral surface of the heat-dissipation heat conductor 221. The insulator 222 may include a first insulator 222a and a second insulator 222b.

The first insulator 222a may be disposed between the heat-dissipation heat conductor 221 and the plurality of light emitters 100 to insulate the heat-dissipation heat conductor 221 and the plurality of light emitters 100. The upper heat conductor 210 may be disposed on a top surface of the first insulator 222a. The height (or thickness) of the first insulator 222a may be lower than the height (or thickness) of the second insulator 222b and the heat-dissipation heat conductor 221. The first insulator 222a enables efficient heat dissipation while maintaining insulation.

The second insulator 222b may be disposed below the first insulator 222a and may be disposed on at least one region of the heat-dissipation heat conductor 221. The height (or thickness) of the second insulator 222b may be greater than the height (or thickness) of the heat-dissipation heat conductor 221 and the first insulator 222a. As a result, heat can be dissipated through the second insulator 222b. Further, the second insulator 222b may include a fiber layer such as carbon fiber, but is not limited thereto. This can enhance structural stability. The second insulator 222b may surround the peripheral surface of the heat-dissipation heat conductor 221. In addition, the second insulator 222b may be formed to surround at least one of the top and bottom regions of the heat-dissipation heat conductor 221. The second insulator 222b can protect the heat-dissipation heat conductor 221 from external impacts, thereby enhancing structural stability.

The support heat conductor 300 may supports the heat conductor unit 200. Furthermore, the support heat conductor 300 together with the heat-dissipation heat conductor 221 may dissipate heat generated from the plurality of light emitters 100. The support heat conductor 300 may be disposed below the heat conductor unit 200. The support heat conductor 300 can transfer heat to the outside, which lowers the thermal resistance of the light emitting device 1 and improves the reliability of the light emitting device 1. For example, the support heat conductor 300 may be a heat sink.

The controller 400 may be provided as a plurality of controllers 400 to control the plurality of light emitters 100 to emit light. The plurality of controllers 400 may be electrically connected to the plurality of light emitters 100 through the plurality of upper heat conductors 210. For example, the plurality of controllers 400 may apply electricity to at least some of the plurality of light emitters 100 so that light is emitted from at least some of the plurality of light emitters 100.

In addition, the plurality of controllers 400 may be spaced apart from each other along the edge of the heat conductor unit 200 in the first and second directions. A distance between the plurality of controllers 400 may be at least about 0.5 times the size of the controller 400. This may minimize or at least suppress thermal interference between each controller 400 and improve reliability. Additionally, the controller 400 may be arranged such that a distance to the edge of the heat conductor unit 200 is less than a distance to the center of the heat conductor unit 200. The distance from the controller 400 to the center of the heat conductor unit 200 may be in the range of about 2 to about 5 times greater than the distance to the edge of the heat conductor unit 200. As a result, heat may be dissipated to the outside, and space utilization may be improved simultaneously. The controllers 400 may be located in the second arrangement region 200c. Further, the light emitter arrangement region 200a may be located inside the plurality of controllers 400. Thus, the light emitter arrangement region 200a may not overlap the plurality of controllers 400 in the plan view. For example, the plurality of controllers 400 may be spaced apart from the plurality of light emitters 100. A distance between the controller 400 and the light emitter 100 may be greater than a distance between the plurality of light emitters 100. The distance between the controller 400 and the light emitter 100 may be at least about 10 times greater than the distance between the plurality of light emitters 100. This may prevent thermal interference between the controller 400 and the light emitter 100, and it may improve reliability. In addition, the distance between the controller 400 and the light emitter 100 may be at least about 5 to about 10 times the length of a cross-section of the light emitter 100. As a result, the controller 400 may not interfere with the light path of the light emitter 100, and the increase in electrical resistance due to the increased distance may be reduced, and it may improve the efficiency of the light emitting device 1.

Meanwhile, the second insulator 222b may cover at least a region of the heat-dissipation heat conductor 221.

Referring to FIG. 2, as a first example, the second insulator 222b may cover both the top and bottom regions of the heat-dissipation heat conductor 221. In particular, the second insulator 222b may include the heat-dissipation heat conductor 221. By this second insulator 222b, the heat-dissipation heat conductor 221 may be disposed within the second insulator 222b and separated from the first insulator 222a and the support heat conductor 300, which prevents the heat-dissipation heat conductor 221 from being corroded or damaged by the external environment. A thickness of a first region of the second insulator 222b, which is disposed above the heat-dissipation heat conductor 221, may be thinner than the thickness of the heat-dissipation heat conductor 221. In addition, a thickness of a second region of the second insulator 222b, which is disposed below the heat-dissipation heat conductor 221, may also be thinner than the thickness of the heat-dissipation heat conductor 221. Furthermore, the sum of the thicknesses of the first and second regions may be within about 10% to about 30% of the thickness of the heat-dissipation heat conductor 221. As a result, heat may be dissipated through the first and second regions, while electrical insulation can be ensured.

Referring to FIG. 3, as a second example, the second insulator 222b may cover the top region of the heat-dissipation heat conductor 221. By this second insulator 222b, at least a surface of the heat-dissipation heat conductor 221 may be in contact with the support heat conductor 300. In particular, the bottom region of the heat-dissipation heat conductor 221 may in direct constant with the top region of the support heat conductor 300. The heat of the heat-dissipation heat conductor 221 may be transferred to the support heat conductor 300, thereby improving thermal characteristics. A thickness of a third region of the second insulator 222b, which is disposed above the heat-dissipation heat conductor 221, may be thinner than the thickness of the heat-dissipation heat conductor 221. The thickness of the third region may be within about 5% to about 20% of the thickness of the heat-dissipation heat conductor 221. Through the third region, heat dissipation may be facilitated while electrical insulation is ensured. For example, the heat-dissipation heat conductor 221 may be formed such that its lower cross-sectional area is greater than its upper cross-sectional area. The contact cross-sectional area of the region of the heat-dissipation heat conductor 221 that contacts the support heat conductor 300 may be larger than the cross-sectional area of the region adjacent to the light emitter 100. As a result, heat may be more transferred toward the support heat conductor 300, thereby improving thermal performance.

Referring to FIG. 4, as a third example, the second insulator 222b may cover the bottom region of the heat-dissipation heat conductor 221. By this second insulator 222b, the upper surface of the heat-dissipation heat conductor 221 may be connected to the first insulator 222a, and the distance between the heat-dissipation heat conductor 221 and the light emitter 100 may be shortened, thereby improving thermal characteristics. A thickness of a fourth region of the second insulator 222b, which is disposed below the heat-dissipation heat conductor 221, may be thinner than the thickness of the heat-dissipation heat conductor 221. The thickness of the fourth region may be within about 5% to about 20% of the thickness of the heat-dissipation heat conductor 221. Accordingly, heat may be effectively dissipated through the fourth region while ensuring electrical insulation. For example, the heat-dissipation heat conductor 221 may be formed such that its bottom cross-sectional area is larger than its top cross-sectional area. The contact cross-sectional area of the region of the heat-dissipation heat conductor 221 in contact with the support heat conductor 300 may be larger than the cross-sectional area of the region adjacent to the light emitter 100. As a result, heat may be more efficiently transferred toward the support heat conductor 300, thereby improving thermal performance.

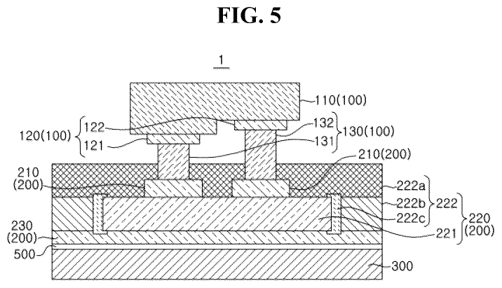

Hereinafter, a light emitting device 1 according to another embodiment of the present disclosure will be described with reference to FIG. 5. FIG. 5 is a schematic diagram showing a light emitting device according to another embodiment of the present disclosure. In describing another embodiment, there are differences in that a surface of the heat-dissipation heat conductor 221 may be in direct contact with the upper heat conductor 210. Thus, the heat conductor unit 200 may further include a lower heat conductor 230 disposed below the heat-dissipation heat conductor 221 and having the same components as the upper heat conductor 210, and the description will focus on these differences. In addition, in describing another embodiment, there are differences in that a connecting heat conductor 500 may be further included, and that the insulator 222 may further include a third insulator 222c, and the description will focus on these differences.

A top surface of the heat-dissipation heat conductor 221 may be in direct contact with a bottom surface of the upper heat conductor 210. The heat-dissipation heat conductor 221 may be laminated on the upper heat conductor 210. Since a surface of the heat-dissipation heat conductor 221 is in direct contact with the upper heat conductor 210, heat may be directly transferred from the upper heat conductor 210 to the heat-dissipation heat conductor 221 without passing through the insulator 222, thereby improving thermal characteristics. The heat-dissipation heat conductor 221 may be made of one of non-conductive heat-conducting materials. In addition, the heat-dissipation heat conductor 221 may have the same height as the second insulator 222b, which improves flatness and enhances structural stability.

The first insulator 222a may cover at least a region of the upper heat conductor 210. In addition, the height of the first insulator 222a may be greater than the height of the upper heat conductor 210. The second heat conductor 130 may penetrate the first insulator 222a and be electrically connected to the upper heat conductor 210.

The third insulator 222c may be disposed between the second insulator 222b and the heat-dissipation heat conductor 221. The third insulator 222c may include an adhesive. The third insulator 222c may prevent separation between the heat-dissipation heat conductor 221 and the second insulator 222b due to thermal stress. At least a region of the third insulator 222c may cover at least a region of the top or bottom surface of the heat-dissipation heat conductor 221, thereby increasing the bonding area and enhancing structural stability.

The third insulator 222c may be arranged to not vertically overlap the upper heat conductor 210. However, the inventive concepts are not limited thereto. In some embodiments, at least a region of the third insulator 222c may be disposed between the upper heat conductor 210 and the heat-dissipation heat conductor 221. For example, the upper heat conductor 210 may include an overlapping region that vertically overlaps the third insulator 222c and a non-overlapping region that does not vertically overlap the third insulator 222c. The non-overlapping region and the overlapping region of the upper heat conductor 210 with respect to the third insulator 222c may have different heights. Due to the third insulator 222c, the bonding area may be increased, thereby improving structural stability

The lower heat conductor 230 may be disposed below the heat-dissipation heat conductor 221. However, some regions of the third insulator 222c may be disposed between heat-dissipation heat conductor 221 and the lower heat conductor 230. The lower heat conductor 230 may have the same composition as the upper heat conductor 210. Since the lower heat conductor 230 and the upper heat conductor 210 may have the same composition, thermal conductivity can be increased. In addition, the lower heat conductor 230 may improve the bending tendency caused by residual stress on the upper and lower surfaces of the heat conductor unit 200, thereby preventing bending of the heat conductor unit 200 and enhancing structural stability. To further enhance structural stability, the area of the lower heat conductor 230 may be similar to that of the upper heat conductor 210. The difference in area between the lower heat conductor 230 and the upper heat conductor 210 may be about 70% or less.

The connecting heat conductor 500 may be disposed between the heat conductor unit 200 and the support heat conductor 300. For example, the connecting heat conductor 500 may be disposed between the lower heat conductor 230 and the support heat conductor 300. The connecting heat conductor 500 may be made of a material having adhesive properties and thermal conductivity. The connecting heat conductor 500 can improve the adhesive strength between the heat conductor unit 200 and the support heat conductor 300, eliminate the air layer between the heat conductor unit 200 and the support heat conductor 300, and improve the heat transfer efficiency and thermal characteristics. The connecting heat conductor 500 may be a fluid material such as thermal grease, a thermal compound, a heat dissipation grease, or a heat transfer paste (HTP), and may be an organic material including a ceramic filler, a metal filler, a carbon filler, or the like. The connecting heat conductor 500 may be vertically overlapped the heat-dissipation heat conductor 221. For example, the area of the connecting heat conductor 500 may be greater than the area of the heat-dissipation heat conductor 221. For example, the area of the connecting heat conductor 500 may be in the range of about 10% to about 20% larger than that of the heat-dissipation heat conductor 221. The connecting heat conductor 500 may support the heat-dissipation heat conductor 221. In addition, the connecting heat conductor 500 may have a smaller area than the support heat conductor 300. The area of the connecting heat conductor 500 may be in the range of about 80% to about 99% of the area of the support heat conductor 300. This may reduce material costs and lower production costs.

Hereinafter, with reference to FIG. 6, a light emitting device 1 according to still another embodiment of the present disclosure will be described. FIG. 6 is a schematic diagram showing a light emitting device according to still another embodiment of the present disclosure. In describing still another embodiment, there are differences in that the heat conductor unit 200 further includes a heat-dissipation pad 240 extending from the upper heat conductor 210 toward the heat-dissipation heat conductor 221, and that the support substrate 220 further includes a transverse heat conductor 223, and the description will focus on these differences.

The heat-dissipation pad 240 may transfer heat of the light emitting unit 110 to the heat-dissipation heat conductor 221. The heat-dissipation pad 240 may be disposed on a surface of the upper heat conductor 210. For example, the heat-dissipation pad 240 may be in direct contact with the heat-dissipation heat conductor 221. The heat-dissipation pad 240 may penetrate the first insulator 222a. The heat-dissipation pad 240 may be disposed between the upper heat conductor 210 and the heat-dissipation heat conductor 221. The heat-dissipation pad 240 may transfer a large amount of heat accumulated in the upper heat conductor 210 to the heat-dissipation heat conductor 221. The heat-dissipation pad 240 may be formed such that the upper heat conductor 210 and the heat-dissipation heat conductor 221 are not electrically connected. For example, at least one of the upper heat conductor 210 and the heat-dissipation heat conductor 221 may be made of an insulation material. This may reduce the complexity of the design.

Alternatively, the heat-dissipation pad 240 may be made of the same material as one or more of the upper heat conductor 210 and the heat-dissipation heat conductor 221. This may improve structural stability by preventing damage to the product from thermal shock. Further, the heat-dissipation pad 240 can protect the light emitting unit 110 by absorbing vibration and shock. In addition, the heat-dissipation pad 240 may be provided as a plurality of heat-dissipation pads.

The plurality of heat-dissipation pads 240 may be spaced apart from each other in the transverse direction and can act as heat conduction fins to increase thermal conductivity. In addition, the cross-sectional area of the heat-dissipation pad 240 may be smaller than the area of the upper heat conductor 210. The heat-dissipation pad 240 may also have a smaller area than the heat-dissipation heat conductor 221. This may prevent the heat-dissipation pad 240 and the heat-dissipation heat conductor 221 from detaching from each other, thereby enhancing structural stability. For example, the area of the heat-dissipation pad 240 may be in the range of about 20% to about 70% of the area of the heat-dissipation heat conductor 221. This may allow improved structural stability while minimizing the impact on the heat path.

The heat-dissipation pad 240 may extend downward from the upper heat conductor 210 toward the heat-dissipation heat conductor 221 and penetrate the insulator 222. For example, the heat-dissipation pad 240 may penetrate the first insulator 222a to be connected to the heat-dissipation heat conductor 221. The heat-dissipation pad 240 may be formed so that its width in the horizontal direction decreases as it goes downward, or conversely, it may be formed so that its width increases as it goes upward. By designing the upper and lower surfaces of the heat-dissipation pad 240 to have different widths, the side contact surface of the heat-dissipation pad 240 increases, which expands the bonding area with the insulator 222, thereby reducing the separation of the heat-dissipation pad 240 due to external impact. For example, the difference between the upper and lower surface areas of the heat-dissipation pad 240 may be in the range of about 2% to about 10%. This may reduce design complexity.

The transverse heat conductor 223 may be disposed between the first insulator 222a and the second insulator 222b or inside the second insulator 222b to be connected to the heat-dissipation heat conductor 221. The transverse heat conductor 223 may be thinner than the first insulator 222a or the second insulator 222b. The thickness of the transverse heat conductor 223 may be in the range of about 1% to about 10% of the thickness of the first insulator 222a or the second insulator 222b. The transverse heat conductor 223 may prevent bending of the heat conductor unit 200, increase heat capacity, and enhance structural stability. A side of the transverse heat conductor 223 may be disposed on the heat-dissipation heat conductor 221, and the other side, opposite to the side, of the transverse heat conductor 223 may be disposed at the edge of the heat conductor unit 200. Alternatively, a side of the transverse heat conductor 223 may be spaced apart from the heat-dissipation heat conductor 221. In addition, the transverse heat conductor 223 may be disposed to be spaced apart from the upper heat conductor 210. The transverse heat conductor 223 may transfer the heat of the heat-dissipation heat conductor 221 to the edge of the heat conductor unit 200 to be released to the outside.

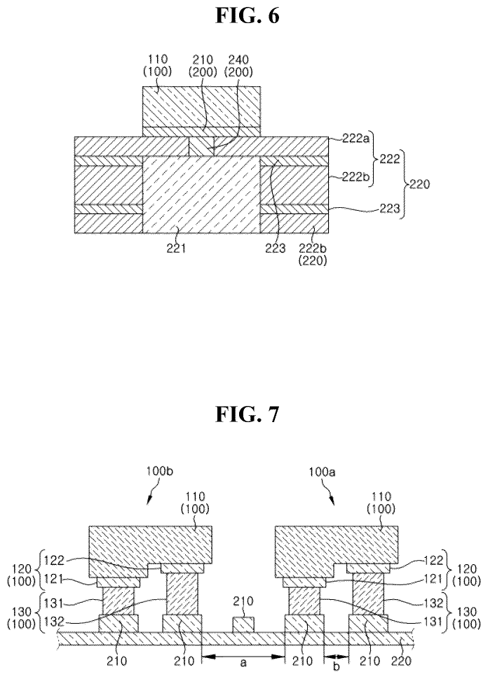

Hereinafter, with reference to FIG. 7, a light emitting device 1 according to still another embodiment of the present disclosure will be described. FIG. 7 is a schematic diagram showing a light emitting device according to still another embodiment of the present disclosure. In describing still another embodiment, there is a difference in that the plurality of light emitters 100 include a first light emitter 100a and a second light emitter 100b, and the description will focus on this difference.

The first light emitter 100a and the second light emitter 100b may be spaced apart from each other. Further, the first light emitter 100a and the second light emitter 100b may not be electrically connected to each other. For example, the controller 400 that controls the first light emitter 100a and the controller 400 that controls the second light emitter 100b may be different. In particular, the first light emitter 100a and the second light emitter 100b may be separately controlled by different controllers 400. In addition, the first light emitter 100a may be a light emitting element included in the first group, and the second light emitter 100b may be a light emitting element included in the second group.

The 2-1 (second-first) heat conductor 131 of the first light emitter 100a may be arranged to face the 2-2 (second-second) heat conductor 132 of the second light emitter 100b. A first separation distance “a” between the 2-1 (second-first) heat conductor 131 of the first light emitter 100a and the 2-2 (second-second) heat conductor 132 of the second light emitter 100b may be different from a second separation distance “b” between the 2-1 (second-first) heat conductor 131 and the 2-2 (second-second) heat conductor 132 of the first light emitter 100a. For example, the first separation distance “a” may be greater than the second separation distance “b”. In addition, the first separation distance “a” may be greater than the separation distance between the 2-1 (second-first) heat conductor 131 and the 2-2 (second-second) heat conductor 132 of the second light emitter 100b, which reduces the thermal influence between the first light emitter 100a and the second light emitter 100b and reduces heat damage, thereby increasing reliability. For example, the first separation distance “a” may be in the range of about 1.5 to about 2.5 times wider than the second separation distance “b”. Through this, thermal interference between devices may be reduced, and space utilization may be improved.

At least one of the plurality of upper heat conductors 210 may be positioned between the first light emitter 100a and the second light emitter 100b. For example, at least one of the plurality of upper heat conductors 210 may extend between the 2-1 (second-first) heat conductor 131 of the first light emitter 100a and the 2-2 (second-second) heat conductor 132 of the second light emitter 100b. The at least one of the plurality of upper heat conductors 210, positioned between the first light emitter 100a and the second light emitter 100b, can dissipate heat between the first light emitter 100a and the second light emitter 100b. Hereinafter, the upper heat conductor 210 located between the first light emitter 100a and the second light emitter 100b may be referred to as an intermediate upper heat conductor.

For example, a separation (or horizontal separation) distance between the intermediate upper heat conductor and the 2-1 (second-first) heat conductor 131 of the first light emitter 100a in the first direction may be in the range of about 35% to about 65% of the separation distance between the 2-1 (second-first) heat conductor 131 of the first light emitter 100a and the 2-2 (second-second) heat conductor 132 of the second light emitter 100b. Alternatively, a separation (or horizontal separation) distance between the intermediate upper heat conductor and the 2-2 (second-second) heat conductor 132 of the second light emitter 100b may be in the range of about 35% to about 65% of the separation distance between the 2-1 (second-first) heat conductor 131 of the first light emitter 100a and the 2-2 (second-second) heat conductor 132 of the second light emitter 100b. This may allow heat to be dissipated to the outside and improve space utilization.

Further, the width of the intermediate upper heat conductor may be in the range of about 40% to about 60% of the width of the 2-1 (second-first) heat conductor of the first light emitter 100a and the 2-2 (second-second) heat conductor of the second light emitter 100b. This enables maintaining electrical stability while improving heat efficiency.

The light emitting device according to embodiments of the disclosure may efficiently dissipate heat, thereby increasing heat dissipation efficiency and improving reliability.

Further, the light emitting device according to embodiments can generate an appropriate amount of light that meets its intended purpose while maintaining a compact size.

In addition, the light emitting device according to embodiments can emit light to form at least one of a high beam pattern and a low beam pattern.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A light emitting device comprising:
a plurality of light emitters configured to emit light; and
a heat conductor unit configured to provide a light emitter arrangement region in which the plurality of light emitters are arranged,
wherein the heat conductor unit includes a heat-dissipation heat conductor configured to dissipate heat generated from the plurality of light emitters, and
wherein an area of the heat-dissipation heat conductor, in a plan view, is larger than an area of the light emitter arrangement region.

2. The light emitting device of claim 1, wherein the heat conductor unit includes:
an upper heat conductor electrically connected to the plurality of light emitters; and
a support substrate including the heat-dissipation heat conductor and configured to support the upper heat conductor.

3. The light emitting device of claim 1, wherein the light emitter arrangement region overlaps the heat-dissipation heat conductor in the plan view.

4. The light emitting device of claim 1, wherein the area of the heat-dissipation heat conductor, in the plan view, is in a range of about 30% to about 80% of an area of the heat conductor unit.

5. The light emitting device of claim 1, wherein:
at least one corner of the heat-dissipation heat conductor has a rounded shape;
the heat conductor unit includes an insulator; and
the heat-dissipation heat conductor is arranged such that its peripheral surface is surrounded by the insulator.

6. The light emitting device of claim 1, wherein the heat-dissipation heat conductor is formed to have a first length in a horizontal direction, a second length in a thickness direction, and a third length perpendicular to the first length and the second length, and
wherein a ratio of the first length to the second length is different from a ratio of the third length to the second length.

7. The light emitting device of claim 1, wherein the heat conductor unit includes a first insulator disposed between the heat-dissipation heat conductor and the plurality of light emitters so that the heat-dissipation heat conductor and the plurality of light emitters are insulated from each other, and
wherein a thickness of the first insulator is lower than a thickness of the heat-dissipation heat conductor.

8. The light emitting device of claim 7, wherein the heat conductor unit further includes a second insulator disposed below the first insulator to cover at least one of top and bottom surfaces of the heat-dissipation heat conductor, and
wherein a thickness of the second insulator is greater than the thickness of the first insulator.

9. The light emitting device of claim 8, further comprising:
a support heat conductor configured to support the second insulator to dissipate heat generated from the plurality of light emitters together with the heat-dissipation heat conductor.

10. The light emitting device of claim 8, wherein the second insulator includes carbon fiber.

11. The light emitting device of claim 2, further comprising:
a plurality of controllers configured to control the plurality of light emitters,
wherein the upper heat conductor includes a plurality of upper heat conductors, and
wherein the plurality of upper heat conductors extend from the plurality of controllers toward the light emitter arrangement region so that the plurality of controllers are electrically connected to the plurality of light emitters.

12. The light emitting device of claim 11, wherein an edge of the heat-dissipation heat conductor is arranged to intersect an imaginary line connecting one of the plurality of controllers and the light emitter positioned closest to the one controller among the plurality of light emitters in the plan view.

13. The light emitting device of claim 2, wherein the upper heat conductor includes a plurality of upper heat conductors, and
wherein the heat conductor unit further provides:
a first arrangement region, located near the light emitter arrangement region, in which some of the plurality of upper heat conductors are arranged; and
a second arrangement region, located farther away from the light emitter arrangement region than the first arrangement region, in which others of the plurality of upper heat conductors are arranged.

14. The light emitting device of claim 13, wherein a density of some of the plurality of upper heat conductors arranged in the first arrangement region is greater than a density of others of the plurality of upper heat conductors arranged in the second arrangement region.

15. The light emitting device of claim 13, wherein the plurality of light emitters include:
a first light emitter; and
a second light emitter that is spaced apart from the first light emitter and is not electrically connected to the first light emitter, and
wherein each of the first light emitter and the second light emitter includes:
a second-first heat conductor electrically connected to the heat-conductor unit;
a second-second heat conductor electrically connected to the heat-conductor unit and spaced apart from the second-first heat conductor; and
a light emitting unit electrically connected to the second-first heat conductor and the second-second heat conductor to generate light.

16. The light emitting device of claim 15, wherein one of the plurality of upper heat conductors is positioned between the second-first heat conductor of the first light emitter and the second-second heat conductor of the second light emitter.

17. The light emitting device of claim 15, wherein a separation distance between the second-first heat conductor of the first light emitter and the second-second heat conductor of the second light emitter is greater than a separation distance between the second-first heat conductor and the second-second heat conductor of the first light emitter.

18. The light emitting device of claim 11, wherein in the plan view, at least some of the plurality of upper heat conductors are bent in a direction different from their extending directions.

19. A light emitting device comprising:
a plurality of light emitters configured to emit light; and
a heat conductor unit configured to provide a light emitter arrangement region in which the plurality of light emitters are arranged,
wherein the heat conductor unit includes a heat-dissipation heat conductor configured to dissipate heat generated from the plurality of light emitters, and
wherein an area of the heat-dissipation heat conductor, when viewed in a first direction, is larger than an area of the light emitter arrangement region.

20. A light emitting device comprising:
a plurality of light emitters configured to emit light; and
a heat conductor unit configured to provide a light emitter arrangement region in which the plurality of light emitters are arranged,
wherein the heat conductor unit includes a heat-dissipation heat conductor configured to dissipate heat generated from the plurality of light emitters, and
wherein an area of the heat-dissipating heat conductor, in a plan view, is larger than an area of the light emitter arrangement region.
